(19) United States
(12) Patent Application Publication
(10) Pub. No.: US 2008/0203545 A1
(43) Pub. Date: Aug. 28, 2008

(54) SEMICONDUCTOR DEVICE AND METHOD OF FABRICATION THEREOF

(75) Inventor: Katsuhiro KATO, Tokyo (JP)

Correspondence Address: VOLENTINE & WHITT PLLC, ONE FREEDOM SQUARE, 11951 FREEDOM DRIVE SUITE 1260, RESTON, VA, 20190, US

(73) Assignee: OKI ELECTRIC INDUSTRY CO., LTD., Tokyo (JP)

(21) Appl. No.: 11/969,965

(22) Filed: Jan. 7, 2008

(30) Foreign Application Priority Data
Feb. 22, 2007 (JP) 2007-042344

(51) Int. Cl. H01L 21/4763; H01L 23/52

(52) U.S. Cl. 257/659; 438/598; 257/E21.495; 257/E23.141

(57) ABSTRACT

A ground line is exposed by removing a surface protecting film, which covers an uppermost metal wiring layer, and providing an opening portion at a portion of a top surface of a semiconductor chip, which portion is within a region contacted by a collet in a pick-up process and corresponds to an upper portion of, among plural metal wires provided at the uppermost metal wiring layer, the ground line which has ohmic connection to a semiconductor substrate. When the collet approaches the top surface of the semiconductor chip in the pick-up process, electrostatic discharge is occurred between the collet and the ground line via the opening portion, and neutralizing charges which have flowed into the ground line directly reach the semiconductor substrate. The semiconductor substrate thereby enters a state of electrostatic equilibrium with a mounting film.

### CROSS-REFERENCE TO RELATED APPLICATION

This application claims priority under 35 USC 119 from Japanese Patent Application No. 2007-042344, the disclosure of which is incorporated by reference herein.

### BACKGROUND OF THE INVENTION

1. Field of the Invention

The present invention relates to a semiconductor device and a method of fabrication thereof, and in particular, to a semiconductor device in which a metal wiring layer, whose surface is covered by a protective film, is formed on the top side of a semiconductor substrate.

2. Description of the Related Art

The semiconductor devices that have the normalized external form and shape, and normalized external electrode configuration, are provided in the semiconductor market as a general plastic packaged component. The semiconductor devices incorporate a semiconductor chip which is formed by an integrated circuit being built-in on a silicon substrate. This semiconductor chip has the terminals of several hundreds from the dozens and the terminals are connected to the metal electrodes for the outer connection which assigned each terminal via gold (Au) wire or the like. The whole periphery of the semiconductor chip, that is included the connecting portion between Au wire and the metal electrode for outside connection, is covered and sealed by resin (plastic) in order to ensure mechanical strength and ease of handling. In the processes of fabricating this type of semiconductor device, the silicon is handled mainly in the form of a wafer. Integrated circuits of a large number of semiconductor devices are simultaneously built-in at the silicon wafer. Then, in the semiconductor device assembly process, the silicon wafer that was stuck to tacky adhesion film (mount film) is cut to length and breadth by the special cutter and be made the piece fragments of many semiconductor chips. After the silicon wafer is cut into a large number of semiconductor chips, a pick-up process is carried out in which the individual semiconductor chips are picked-up and transferred to the next process.

In the semiconductor chip pick-up process, an adsorption device for pick-up (called a collet) is made to approach the semiconductor chip which is the object of pick-up, and adsorbs the semiconductor chip, and in this state, the collet is moved upward. In this way, the semiconductor chip which is the object of pick-up is peeled-off from the mounting film and picked-up. At this time, the mounting film to which the semiconductor chips are adhered is electrostatically charged because it slidingly moves on a stage made of metal. The individual semiconductor chip that is stuck to mount film is easy to receive the flow such neutralized electric charge for balancing to the electrified mount film. Therefore, when the collet approaches the semiconductor chip, there are cases in which electrostatic discharge is occurred between the semiconductor chip and the collet.

Japanese Patent Application Laid-Open (JP-A) No. 9-45749 discloses the technology that prevents the electrostatic discharge damage of the constitution element such as the transistor that is composing the TFT panel. In this technology, when the TFT panel was peeled off from the dicing film to send to the next process, the collet that was grounded is contacted to the terminal of the TFT panel. According to this technology, the electric charge that was generated to the TFT panel when the TFT panel peeled off from the dicing film, dissipating this electric charge through the grounded collet and it is able to prevent the electrostatic discharge damage.

As shown in FIGS. 9A and 9B, in the pick-up process, there is conventionally used a collet in which the configuration of the bottom portion thereof is rectangular and the surface area of the bottom is larger than the surface area of the top surface of the semiconductor chip which is the object of pick-up. When the semiconductor chip which is the object of pick-up is picked-up, the peripheral edge portion of the top surface is contacted by the collet. Therefore, in the conventional pick-up process, electrostatic discharge at the time of pick-up also occurs between the collet and the side surfaces of the semiconductor chip, and neutralizing charges are safely supplied to the silicon substrate. More specifically, the neutralizing electric charge is supplied to the silicon substrate directly from the collet by the discharge through the space (the air gap) between the collet and side edge of semiconductor chip. The region where this silicon substrate is exposing is called a grid line. Therefore, even if electrostatic discharge occurred, trouble such as electrostatic damage or the like is not caused at the integrated circuit which is formed on the semiconductor chip.

However, in recent years, accompanying the increase in size of semiconductor chips, the size of the collets which are used in the pick-up process has become relatively small. As shown as an example in FIGS. 10A and 10B, there have come to be used collets in which the surface area of the bottom is smaller than the surface area of the top surface of the semiconductor chip which is the object of pick-up, and which absorb the semiconductor chip by directly contacting the top surface of the semiconductor chip at substantially the central portion of the top surface of the semiconductor chip (chip-surface-contacting collets). Note that, because the central portion of the bottom surface of the collet is an air passage, the region that the chip-surface-contacting collet contacts at the top surface of the semiconductor chip is a region corresponding to a rectangular frame if the bottom surface of the collet is square (rectangular), and is a region corresponding to an oval frame if the bottom surface of the collet is oval.

As described above, in a case in which the collet contacts the top surface of the semiconductor chip at the time of picking-up the semiconductor chip, it is difficult for electrostatic discharge between the collet and the side surfaces of the semiconductor chip to occur as was the case conventionally. As shown in FIG. 11 for an example, the dielectric breakdown is caused to the surface protection film (it is called passivation film) that was formed in the top of the semiconductor chip, by the electrostatic discharge between the collet and the chip surface of collet contacting portion. And, the neutralizing charge flows into the silicon substrate through the metal interconnects that existing under the regions which contact with collet directly. In this way, there is the problem that serious trouble, such as electrostatic damage or the like, may occur at the integrated circuit formed at the semiconductor chip. FIG. 11 shows the example that the gate oxide film breakdown of the NMOS transistor that existing on the inflow route of the neutralization charge by electrostatic discharge.

Note that there are collets which are made with conductive materials and collets which are made with insulating materials. There is the possibility that the trouble becomes more severe, because the electrostatic discharge is accumulated that accompanies the electrification of collet itself in addition to the electrostatic discharge associated with the electrification of mount film, when using the collet that was made with insulating material. Because of this, the collets are often made with the conductive material (e.g., a conductive rubber) and are grounded to prevent electrification.

However, even if the collet is grounded the electrostatic discharge that causes the trouble of an integrated circuit occurs because there is a cause in the electrified mount film. Also, to prevent or to reduce the electrification of mount film, the ionized air that produced from an ionizer is tried to blow to electrified mount film, However, because the mounting film is slidingly-conveyed on a metal stage at a high speed, even if such a countermeasure is employed, it is not possible to eliminate charging of the mounting film, and the occurrence of electrostatic discharge cannot be prevented.

By the way, the technology that was disclosed with JP-A No. 9-45749, dissipate the electric charge that generated into the TFT panel through the collet. And as for the direction of the migration of the electric charge dissipation, the discharge phenomenon that was explained heretofore as the neutralization electric charge introduced from the collet is an opposite direction. Even if the technique disclosed in JP-A No. 9-45749 were applied, because electrostatic discharge is occurred also the collet is grounded as described above, the occurrence of trouble due to electrostatic discharge cannot be prevented. Further, in the technique disclosed in JP-A No. 9-45749, the terminals of the TFT panel which contact the collet are signal terminals that are configured in the periphery location of the TFT panel and the drive signals for internal transistor are supplied. In the technique disclosed in JP-A No. 9-45749, for example there is the possibility that the excessive surge current flows to the inside transistor, by the change of the sudden electric field, when the TFT panel was peeled off from dicing film vigorously, and it is difficult to prevent the failure by the electrostatic damage.

### SUMMARY OF THE INVENTION

The present invention was developed in view of the aforementioned, and an object thereof is to provide a semiconductor device in which failure of an integrated circuit due to electrostatic discharge between the semiconductor device and a collet in a pick-up process can be prevented, and a method of fabricating the semiconductor device.

In order to achieve the above-described object, a semiconductor device of a first aspect of the present invention is a semiconductor device at which an integrated circuit is formed, and at which a metal wiring layer, whose surface is covered by a protective film, is formed at an upper side of a semiconductor substrate, wherein a first specific metal wire, which has an ohmic connection to a region of a first conductive type of the semiconductor substrate, is exposed due to the protective film being removed at a first portion which is within a specific region on a surface of the protective film and which corresponds to an upper portion of, among a plurality of metal wires which are provided at the metal wiring layer, the first specific metal wire.

At the semiconductor device of the first aspect of the present invention, the integrated circuit is formed, and the metal wiring layer, whose surface is covered by the protective film, is formed at the upper side of the semiconductor substrate. Note that the semiconductor device relating to the present invention may be structured such that plural metal wiring layers are provided. In this case, “a metal wiring layer, whose surface is covered by a protective film” corresponds to the uppermost metal wiring layer among the plural metal wiring layers which are provided. Here, in the first aspect of the present invention, the first specific metal wire, which has an ohmic connection to a region of a first conductive type of the semiconductor substrate, is exposed due to the protective film being removed at the first portion which is within a specific region on the surface of the protective film, and which corresponds to an upper portion of, among the plural metal wires provided at the metal wiring layer, the first specific metal wire.

Here, the dielectric breakdown voltage of the protective film which covers the metal wiring layer is clearly higher than that of air. When a certain object (e.g., a collet) approaches to the semiconductor device that is easy to receive neutralizing electric charge, electrostatic discharge occurs between the approaching object and the first specific metal wire which is exposed at the first portion. It is because only air exists (the protective film does not exist) between the approaching object and the first specific metal wire. Further, because the first specific metal wire has an ohmic connection to a region of the first conductive type of the semiconductor substrate, the neutralizing charges, which have flowed into the first specific metal wire of the semiconductor device due to the above-described electrostatic discharge, go through only the first specific metal wire (do not go through the integrated circuit formed at the semiconductor device) and reach the semiconductor substrate.

In this way, by using the region which the collet contacts in the pick-up process in which the semiconductor device is picked-up, or a region in a vicinity thereof, as the specific region (a fifth aspect), even when the semiconductor device is easy to receive neutralization electric charge, the neutralizing charges which flow into the semiconductor device due to electrostatic discharge between the semiconductor device and the collet in the pick-up process can be prevented from going through the integrated circuit. Therefore, failure of the integrated circuit due to electrostatic discharge between the semiconductor device and the collet in the pick-up process can be prevented. Further, in most semiconductor devices, a metal wire, which has an ohmic connection to a region of the first conductive type of the semiconductor substrate and which functions as a ground line, is included among the plural metal wires which are provided at the metal wiring layer. This metal wire is disposed at respective places of the entire surface of the metal wiring layer, and can be used as the first specific metal wire. Therefore, in order to apply the first aspect of the present invention, there is no need to add a metal wire which is used as the first specific metal wire to the metal wiring layer of an existing semiconductor device. Further, in carrying out picking-up of the semiconductor device relating to the present invention, there is no need to change the configuration, size, material, or the like of the collet.

In most semiconductor devices, a metal wire (the second specific metal wire), which has an ohmic connection to a region of the second conductive type of well formed on the semiconductor substrate and which functions as a power source line, is also included among the plural metal wires which are provided at the metal wiring layer. This second specific metal wire also is disposed at respective places of the entire surface of the metal wiring layer. In regard thereto, in a case in which the semiconductor device of the first aspect of the present invention is structured such that neutralizing charges flow in only to the first specific metal wire, a potential difference generated between the first specific metal wire and the second specific metal wire albeit for only an instant (an extremely short time interval), and there is the possibility that high voltage will be applied to the integrated circuit which is formed at the semiconductor device and interposed between the first specific metal wire and the second specific metal wire. In consideration thereof, in the first aspect of the present invention, it is preferable that the second specific metal wire, which has an ohmic connection to a region of a second conductive type of well formed on the semiconductor substrate, be exposed due to the protective film being removed also at a second portion which is within the specific region and which corresponds to an upper portion of, among the plural metal wires provided at the metal wiring layer, the second specific metal wire (second aspect).

In this way, when a certain object (e.g., a collet) approaches to the semiconductor device that is easy to receive neutralizing electric charge, electrostatic discharge occurs between the approaching object and the first specific metal wire which is exposed at the first portion, and also electrostatic discharge occurs between the approaching object and the second specific metal wire which is exposed at the second portion independently. Therefore, it is possible to prevent a potential difference from occurring between the first specific metal wire and the second specific metal wire, and high voltage from being applied to the integrated circuit which is interposed between the first specific metal wire and the second specific metal wire. Accordingly, in accordance with the second aspect of the present invention, failure of the integrated circuit due to electrostatic discharge between the semiconductor device and the collet in the pick-up process can be even more reliably prevented.

Further, the semiconductor device relating to the present invention may be structured with plural circuit blocks, each circuit block has the ground line and power source line of the exclusive use and they are provided at respectively different positions on the substrate surface of the semiconductor substrate (at this constitution). In this structure, even the ground line that belongs to any circuit blocks is able to use it as the first specific metal wire, and also even the power source line that belongs to any circuit blocks is able to use it as the second specific metal wire in this structure. However, for example, when the second circuit block is being configured in the particular substrate surface where the collet approaches, and the first circuit block is being configured in the place that is distant from the approach place of collet, and the ground line that belongs to this first circuit block is chosen as the first specific metal, and also, the power source line that belongs to this first circuit block is chosen as the second specific metal, the second circuit block is exposed to the danger of the electrostatic discharge only a very short period (an extremely short period: the period means the neutralizing charges which have flowed into the metal wire of the first circuit block go through the semiconductor substrate and attain to this second circuit block). Especially, among the metal wires that are being configured in the particular substrate surface where the collet approaches, there is the danger that the more usual signal wire than ground wire and also power source wire, causes the dielectric breakdown and rushing of neutralizing electric charge. Namely, the integrated circuit inside the circuit block that is being configured in the particular substrate surface where the collet approaches is exposed to the danger of failure.

In consideration of the above, in the second aspect of the present invention, in a case of semiconductor device with plural circuit blocks, each circuit block has the ground line and power source line of the exclusive use and they are provided at respectively different positions on the substrate surface of the semiconductor substrate as for the first specific metal wire, it is designated desirably the ground wire which belongs to the circuit-block that is being configured in the particular substrate surface where the collet approaches, and also as for the second specific metal wire, it should be designated the power source wire which belongs to the circuit-block that is being configured in the particular substrate surface where the collet approaches (third aspect).

Because of the ground wire, which belongs to the circuit-block that is being configured in the particular substrate surface where the collet approaches, takes the role of the first specific metal wire, and also the power source wire, which belongs to the circuit-block that is being configured in the particular substrate surface where the collet approaches, takes the role of the second specific metal wire, the integrated circuit is able to prevent the trouble due to protection film on signal wire causes the dielectric breakdown.

In this way, in accordance with the third aspect of the present invention, among the plural circuit blocks which are provided at the semiconductor device, the circuit block, which has the highest degree of danger of the integrated circuit within the circuit block breaking-down, can be reliably protected.

Further, in the first aspect of the present invention, for example, a metal wire which is not electrically connected with any kind of logic circuit formed at the semiconductor device may be used as the first specific metal wire (fourth aspect). In this case, although there is the need to form the metal wire, which is to be used only as the first specific metal wire, at the semiconductor device in advance, failure of the integrated circuit due to electrostatic discharge between the semiconductor device and the collet in the pick-up process can be prevented even more reliably.

Further, in the first aspect of the present invention, for example, a metal wire, which includes a portion formed on a high-concentration semiconductor region of the first conductive type which is formed within the low-concentration semiconductor region of the first conductive type, may be used as the first specific metal wire which is electrically connected to the high-concentration semiconductor region of the first conductive type of the semiconductor substrate (sixth aspect). Moreover, in the second aspect of the present invention, for example, a metal wire, which includes a portion formed on a high-concentration semiconductor region of the second conductive type which is formed within the low-concentration semiconductor region of the second conductive type, may be used as the second specific metal wire which is electrically connected to the high-concentration semiconductor region of the second conductive type of well formed on the semiconductor substrate (seventh aspect).

An eighth aspect of the present invention is a method of fabricating a semiconductor device including: producing a semiconductor device at which an integrated circuit is formed, and at which a surface of a metal wiring layer, which is formed at an upper side of a semiconductor substrate, is covered by a protective film; and, before carrying out a pick-up process of picking-up the semiconductor device, exposing a first specific metal wire, which has an ohmic connection to a region of a first conductive type of the semiconductor substrate, at a first portion by removing the protective film at the first portion which is within a specific region on a surface of the protective film and which corresponds to an upper portion of, among a plurality of metal wires which are provided at the metal wiring layer, the first specific metal wire. Accordingly, in the same way as in the first aspect of the present invention, failure of the integrated circuit due to electrostatic discharge between the semiconductor device and the collet in the pick-up process can be prevented.

Note, the bonding pads which are for connection with metal electrodes for external connection, are provided at the semiconductor device. Generally, in the processes of fabricating a semiconductor device, after the protective film is once formed, a removing process which removes the protective film which covers these bonding pads is carried out. Therefore, exposing the first specific metal wire by removing the protective film at the first portion can be carried out simultaneously with the aforementioned removing process. Therefore, in fabricating the semiconductor device relating to the present invention, there is no need to change the fabricating processes themselves, and the semiconductor device relating to the present invention can be fabricated easily.

A ninth aspect of the present invention has the feature that, in the eighth aspect, before the pick-up process is carried out, a second specific metal wire, which has an ohmic connection to a region of a second conductive type of well formed on the semiconductor substrate, is exposed at a second portion due to the protective film being removed at the second portion which is within the specific region and which corresponds to an upper portion of, among the plurality of metal wires which are provided at the metal wiring layer, the second specific metal wire. Therefore, in the same way as in the second aspect of the present invention, failure of the integrated circuit due to electrostatic discharge between the semiconductor device and the collet in the pick-up process can be prevented even more reliably.

In the eight or ninth aspect of the present invention, for example, a region of the surface of the protective film, which region is contacted by a collet in the pick-up process in which the semiconductor device is picked-up, can be used as the specific region (tenth aspect). Further, in the tenth aspect of the present invention, a bottom surface area of the collet may be made to be smaller than, for example, a surface area of a surface of the semiconductor device, which surface has a region that the collet contacts (eleventh aspect).

As described above, in the present invention, the first specific metal wire, which has an ohmic connection to a region of a first conductive type of the semiconductor substrate, is exposed by removing the protective film at the first portion which is within a specific region on the surface of the protective film covering the surface of the metal wiring layer of the semiconductor device, and which corresponds to an upper portion of, among the plural metal wires which are provided at the metal wiring layer, the first specific metal wire. Therefore, the present invention has the excellent effect that failure of an integrated circuit due to electrostatic discharge between the semiconductor device and a collet in a pick-up process can be prevented.

### BRIEF DESCRIPTION OF THE DRAWINGS

Preferred exemplary embodiments of the present invention will be described in detail based on the following figures, wherein:

FIG. 1A is a plan view of a semiconductor device relating to a first exemplary embodiment;

FIG. 1B is an enlarged plan view of the portion indicated by the broken lines in FIG. 1A;

FIG. 2 is a schematic drawing showing a flow-in path of neutralizing charges in a pick-up process at the semiconductor device shown in FIG. 1;

FIG. 3 is a flowchart showing an outline of processes of fabricating the semiconductor device;

FIG. 4A is a plan view of a semiconductor device relating to a second exemplary embodiment;

FIG. 4B is an enlarged plan view of the portion indicated by the broken lines in FIG. 4A;

FIG. 5 is a schematic drawing showing (a portion of) a flow-in path of neutralizing charges in a pick-up process at the semiconductor device shown in FIG. 4;

FIG. 6A is a plan view of a semiconductor device at which plural circuit blocks are provided;

FIG. 6B is a schematic drawing showing a flow-in path of neutralizing charges in a case in which opening portions are provided at wires of the respective circuit blocks (not desirable case);

FIG. 6C is a schematic drawing showing a flow-in path of neutralizing charges in a case in which opening portions are provided at wires of the respective circuit blocks (desirable case);

FIG. 7A is a plan view of a semiconductor device relating to a third exemplary embodiment;

FIG. 7B is an enlarged plan view of the portion indicated by the broken lines in FIG. 7A;

FIG. 8 is a schematic drawing showing a flow-in path of neutralizing charges in a pick-up process at the semiconductor device shown in FIG. 7;

FIG. 9A is a schematic drawing showing a conventional pick-up process;

FIG. 9B is a partial enlarged view of FIG. 9A;

FIG. 10A is a schematic drawing showing a pick-up process by a chip-surface-contacting collet of the present invention;

FIG. 10B is a partial enlarged view of FIG. 10A; and

FIG. 11 is a schematic drawing showing, in the pick-up process of FIG. 10A and FIG. 10B, an example in which a gate oxide film of an NMOS transistor is broken due to the flowing-in of neutralizing charges due to electrostatic discharge.

### DETAILED DESCRIPTION OF THE INVENTION

Examples of exemplary embodiments of the present invention will be described in detail hereinafter with reference to the drawings.

### First Exemplary Embodiment

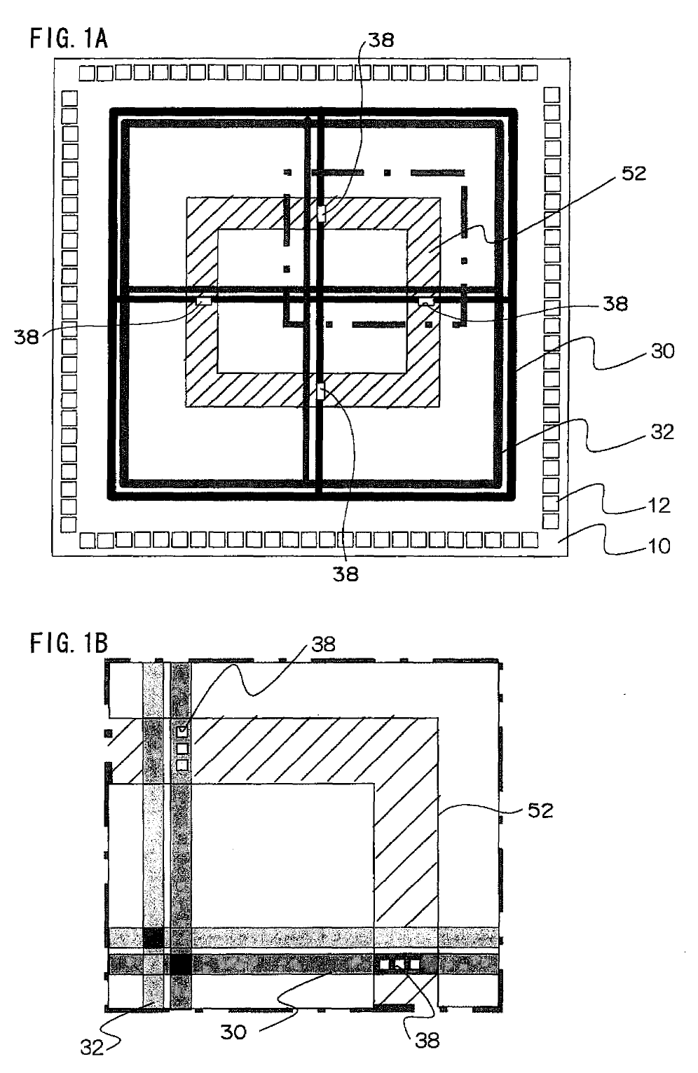

A semiconductor chip 10 which is built-into a semiconductor device relating to the present first exemplary embodiment is shown in FIG. 1A. A large number of pads (electrodes) 12 for external connection are arrayed at the outer peripheral portion of the top surface of the semiconductor chip 10. The semiconductor device relating to the present first exemplary embodiment is structured such that the individual pads 12 of the semiconductor chip 10 are respectively connected to a large number of metal electrodes for external connection (not shown) via Au wires or the like. The semiconductor chip 10 is covered and sealed by resin so that the connected portion of the pads 12 and Au wires, the connected portion of Au wires and the metal electrodes for external connection, are covered, the portions of the metal electrodes for external connection are exposed to the exterior.

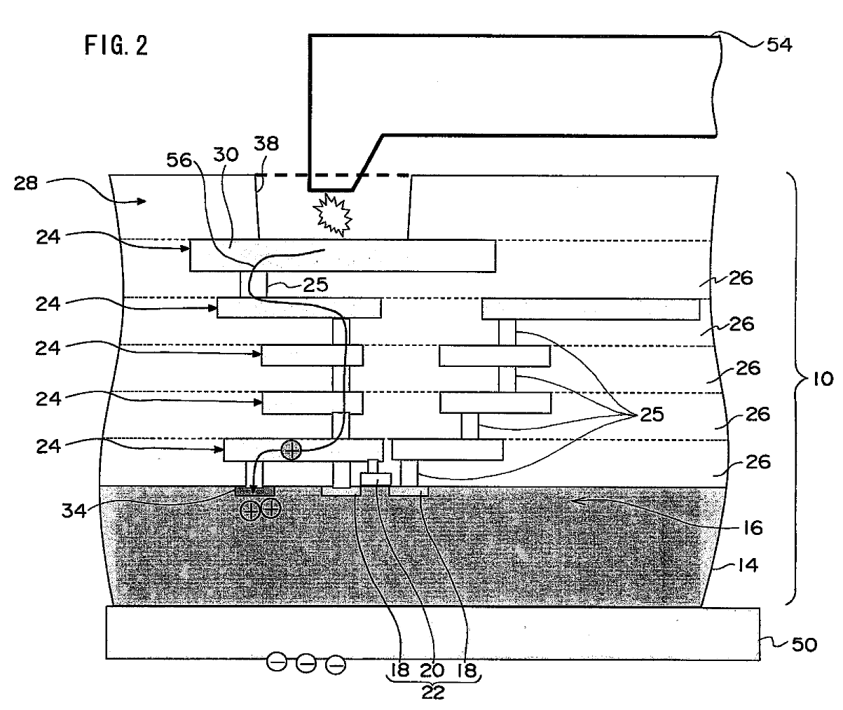

As shown in FIG. 2, the semiconductor chip 10 has a semiconductor substrate 14 which is made of a semiconductor material such as silicon or the like. An integrated circuit 16 is formed on the semiconductor substrate 14. Note that, in FIG. 2, an n-type MOS transistor 22 is illustrated as the integrated circuit 16. The n-type MOS transistor 22 is composed with a pair of n-type impurity diffusion regions 18, which are formed on a p-type substrate 14 and which each function as a source or a drain, and a gate electrode 20 which is formed between the pair of n-type impurity diffusion regions 18. An unillustrated gate oxide film insulates between the gate electrode 20 and a p-type substrate 14.

Plural metal wiring layers 24 are stacked so as to be spaced apart by distances above the semiconductor substrate 14. In FIG. 2, an example in which five of the metals wiring layers 24 are stacked is shown. Interlayer insulating films 26 are respectively stacked between the semiconductor substrate 14 and the lowermost metal wiring layer 24, and between the respective metal wiring layers 24. The metal wiring layers 24 of each layer include the enormous number of metal wirings which are divided mutually. These metal wirings create the whole function of the semiconductor device. For that, each metal wiring connects mutually the circuit blocks which are formed at different place in integrated circuit 16, and also, some metal wiring connects the circuit block and specific pads 12. At this time, the metal wirings that belong to same wiring layer are connected mutually through another metal wiring which belongs to upper or lower metal wiring layer 24. Further, the surface of the uppermost metal wiring layer 24 is covered by a surface protecting film 28.

As shown in FIG. 1A, a metal wire 30 (hereinafter simply called “ground line 30”), which functions as a ground line, and a metal wire 32 (hereinafter simply called “power source line 32”), which functions as a power source line, are respectively provided at the uppermost metal wiring layer 24. Because the ground line 30 and the power source line 32 are connected to many places of the integrated circuit 16, they are railed over the entire surface of the uppermost metal wiring layer 24 so as to go round the uppermost metal wiring layer 24 as shown in FIG. 1A. As shown in FIG. 2, the ground line 30 is electrically connected, through several lower metal wiring layers 24 and vias 25, to a high-concentration p-type semiconductor region 34 which is formed on the semiconductor substrate 14, and has an ohmic connection to the semiconductor substrate 14.

Here, in the present first exemplary embodiment, the ground line 30 is used as a first specific metal wire relating to the present invention as will be described later. Furthermore, the metal wire which is used as the first specific metal wire (or a second specific metal wire) relating to the present invention is preferably ohmically connected to the semiconductor substrate 14 (or n-type well 62) for rapid discharge of neutralizing charges as will be described later Namely, an ohmic connection is a connection in which the voltage and current are in a proportional relationship. In a case in which, as in the present first exemplary embodiment, the metal wire which is used as the first specific metal wire (or the second specific metal wire) relating to the present invention electrically connects to the high-concentration p-type impurity diffusion region 34 within the p-type semiconductor substrate 14, this metal wire and the semiconductor substrate 14 are ohmically connected. In the case that the metal wire electrically connects to non high-concentration impurity diffusion region within the p-type semiconductor substrate 14, the connection becomes Schottky connection. As another case, the metal wire electrically connects to a high-concentration n-type impurity diffusion region within the p-type semiconductor substrate 14, the connection becomes diode connection. Contrastively in the present first exemplary embodiment, the metal wire has an ohmic connection to the semiconductor substrate 14. Although the effects of the present invention may be achieved to some extent also in the Schottky connection or diode connection, the effects of the present invention can be achieved more effectively in the ohmic connection.

As shown in FIG. 1 and FIG. 2, a collet 54 contacts the contact region 52 of top surface of semiconductor chip 10 in the pick-up process which will be described later. Furthermore, as shown in FIG. 1B and FIG. 2, the surface protection film 28 is removed from the places which are buried ground wire inside of this contact region 52. The ground wire 30 is exposing on that opening portions 38 because the surface protection film is removed (these portions correspond to first portions relating to the present invention). Note that the ground line 30 corresponds to the first specific metal wire relating to the present invention.

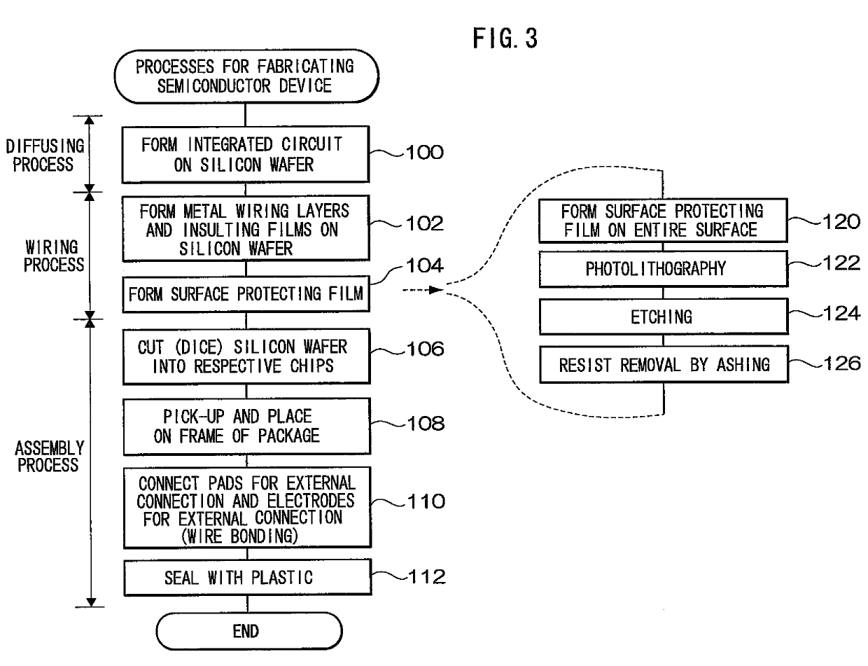

The processes for fabricating the semiconductor device relating to the present first exemplary embodiment will be described next with reference to FIG. 3. The semiconductor device is fabricated via the respective processes of diffusion, wiring, and assembly. In the diffusion process, integrated circuits of a large number of semiconductor chips 10 which are formed from a large number of semiconductor elements respectively, are simultaneously formed on a single silicon wafer (step 100) by repeating, plural times and on the silicon wafer (the substrate), the processings of oxidation, ion implantation by injecting impurities, diffusion, photolithography which transfers a mask pattern onto a photo-resist, etching which removes unnecessary portions in accordance with the mask pattern so as to form a device pattern, ashing which removes the photo-resist and the like.

In the wiring process, first, processings which carry out formation of the interlayer insulating film 26 and the metal wiring layer 24 and the vias 25 by CVD, sputtering or evaporation, and photolithography, etching, ashing, and the like, are repeated plural times on the silicon wafer so as to form the plural layers of the metal wiring layers 24, the interlayer insulating films 26 and the vias 25 on the silicon wafer (step 102). The vias 25 mutually connect the upper metal wirings 24 and the lower metal wirings 24 at desired positions. Thereafter, the processing of forming the surface protecting film 28 on the surface of the uppermost metal wiring layer 24 is carried out (step 104).

In the assembly process, first, dicing is carried out which cuts the silicon wafer, on which the interlayer insulating films 26, the metal wiring layers 24 and the surface protecting film 28 are formed, into units of the individual semiconductor chips 10 (step 106). Note that, at the time of carrying out dicing, the silicon wafer is adhered to a mounting film, and the silicon wafer is cut in the dicing process. Next, a pick-up process is carried out which peels the semiconductor chip 10 off from the mounting film by adsorbing and picking-up the semiconductor chip 10 by the collet 54, and the picked-up semiconductor chip 10 is placed on the frame of a semiconductor device package (step 108). Then, wire bonding, which connects the pads 12 of the semiconductor chip 10 to metal electrodes for external connection by Au wires or the like, is carried out (step 110). The semiconductor chip 10 is covered and sealed by resin (step 112) such that the connected portion of the pads 12 and Au wires, the connected portion of Au wires and the metal electrodes for external connection, are covered, the portions of the metal electrodes for external connection are exposed to the exterior. The semiconductor device is thereby completed.

Note that, in the semiconductor chip 10 relating to the present first exemplary embodiment, the opening portions 38 are the places where the surface protection film 28 is removed and where are buried ground wire 30 inside of the contact region 52. These opening portions 38 can be provided by carrying out formation of the surface protecting film 28 (step 104) as follows.

Namely, because the pads 12 which are provided at the semiconductor chip 10 are connected to the metal electrodes for external connection by Au wires as described above, the pads 12 must be exposed without being covered by the surface protecting film 28. Therefore, the formation of the surface protecting film 28 in step 104 is accomplished by, more specifically, forming the surface protecting film 28 on the entire top surface of the semiconductor chip 10 by film-forming an insulating material by CVD or the like on the surface of the uppermost metal wiring layer 24 (step 120), and thereafter, transferring a mask pattern, which is for removing the surface protecting film 28 at the area of upper surface of the pads 12, onto a photo-resist by photolithography (step 122), and then removing the unnecessary portions (the area of upper surface of the pads 12) of the surface protecting film 28 by etching in accordance with the transferred mask pattern (step 124), and removing the resist by ashing (step 126).

Accordingly, providing the opening portions 38 which are the places where the surface protection film 28 is removed and where are buried ground wire 30 inside of the contact region 52, can be realized by using, as the mask pattern which is transferred onto the photo-resist by photolithography, a mask pattern for removing the surface protecting film 28 at the area of upper surface of pads 12 and at portions where are buried ground wire 30 inside of the contact region 52, instead of a conventional mask pattern for removing only the surface protecting film 28 at the area of upper surface of pads 12. In this way, the fabrication of the semiconductor chip 10 relating to the present first exemplary embodiment (the semiconductor chip 10 at which the opening portions 38 (or opening portions 40 or opening portions 94 which will be described later) are provided at the surface protecting film 28) does not require changing of any of the respective processes for fabricating a semiconductor chip. Because the fabrication of the semiconductor chip 10 relating to the present first exemplary embodiment can be realized merely by changing the mask pattern which is used at the time of forming the surface protecting film 28 (specifically, at the time of removing the unnecessary portions of the surface protecting film 28), fabrication is easy.

Operation of the opening portions 38 at the time when the pick-up process is carried out on the semiconductor chip 10 relating to the present first exemplary embodiment will be described next. When the pick-up process is carried out, as shown in FIG. 2, the semiconductor chip 10 is in a state in which a mounting film 50 is adhered to the reverse surface thereof and the semiconductor chip 10 is held by the mounting film 50. In the pick-up process, pick-up processing is carried out in which the collet 54 is made to contact, of the top surface of the semiconductor chip 10, the contact region 52 which is shown in FIG. 1A, and thereafter, by causing the collet 54 to adsorb the semiconductor chip 10 by negative pressure and by moving the collet 54 upward in this state, the semiconductor chip 10 is peeled-off from the mounting film 50, and is transferred to the next process (the process of placing the semiconductor chip 10 at a predetermined position on the frame of a semiconductor device package).

In the pick-up process shown with FIG. 2, the mounting film 50, on whose top surface are adhered the piece fragments of semiconductor chips 10 moves while contacting the metal stage. At this time, static electricity generates at the bottom surface of the mounting film 50 due to the friction between the bottom surface and the stage. The semiconductor substrate 14, which is stuck to the charged mounting film, is in a state in which it easily receives neutralizing charges for balancing the charges which the mounting film has.

Therefore, when the collet 54 approaches the top surface of the semiconductor chip 10 in order to carry out the pick-up processing, electrostatic discharge occurs between the collet 54 and the semiconductor chip 10, and the neutralizing charges flow into the semiconductor chip 10.

In contrast, at the semiconductor chip 10 relating to the present first exemplary embodiment, the opening portions 38 are provided by removing the surface protecting film 28, of the top surface of the semiconductor chip 10, portions which are within the contact region 52 of the collet 54 and correspond to directly above the ground line 30. The dielectric breakdown voltage of the air which fills these opening portions 38 is clearly lower than that of the surface protecting film 28 which is formed from an insulating material. Therefore, when the collet 54 approaches the top surface of the semiconductor chip 10 in the pick-up process, electrostatic discharge occurs, via the opening portions 38, between the collet 54 and the ground line 30 which is exposed at the opening portions 38, and neutralizing charges flow into the ground line 30. Because the ground line 30 has ohmic connection to the semiconductor substrate 14 through several lower metal wiring layers 24 and vias 25, the neutralizing charges which have flowed into the ground line 30 due to the aforementioned electrostatic discharge reach the semiconductor substrate 14 along a path 56 shown in FIG. 2 (without going through the integrated circuit 16 formed at the semiconductor substrate 14), and the semiconductor chip 10 is set in a state of electrostatic equilibrium with the electrified mounting film 50. Accordingly, failures such as electrostatic damages or the like can be prevented from occurring at the integrated circuit 16 formed at the semiconductor substrate 14 due to electrostatic discharge between the semiconductor chip 10 and the collet 54 in the pick-up process.

Note that, in FIG. 2, the width of the opening portion 38 is illustrated as being larger than the width of top end of collet 54 and is shown the top end of collet 54 is entered into the opening portion 38. In this way, it is suitable for the width of the opening portion 38 to be larger than the width of the distal end of the collet 54. This is because the distal end of collet 54 can be positioned inside the opening portion 38 even if the position of the collet 54 is offset somewhat from the opening portion 38 in the pick-up process. Note that actual electrostatic discharge between the semiconductor chip 10 and the collet 54 is expected to occur as air gap discharge before the both contact one another. This is due to the difference in the dielectric breakdown voltages of the surface protecting film and the air. Accordingly, the width of the opening portion 38 may be made to be smaller than the width of the distal end of the collet 54.

### Second Exemplary Embodiment

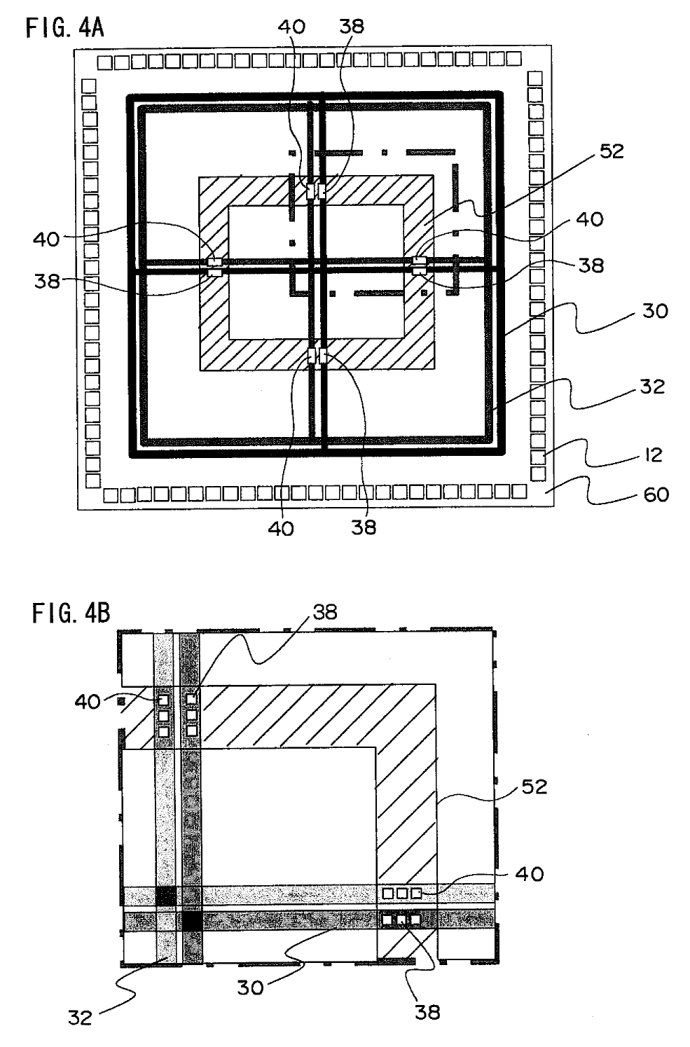

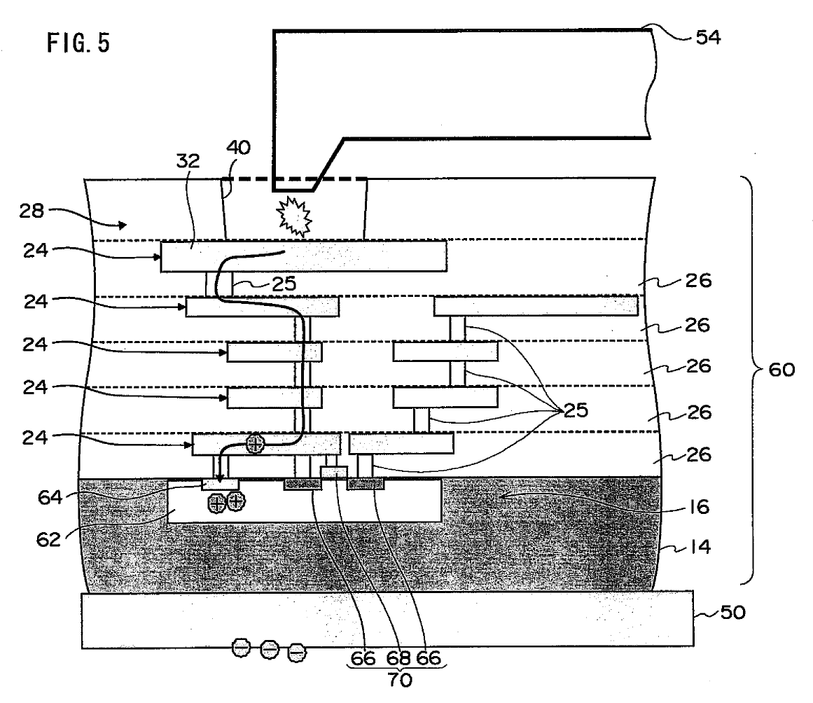

Next, a second exemplary embodiment of the present invention will be described. Note that portions which are the same as those of the first exemplary embodiment are denoted by the same reference numerals, and description thereof is omitted. A semiconductor chip 60 relating to the present second exemplary embodiment is shown in FIGS. 4A and 4B and in FIG. 5. In the semiconductor chip 10 which was described in the first exemplary embodiment, the opening portions 38 are provided at plural portions corresponding to directly above the ground line 30, within the contact region 52 of the collet 54 on the top surface of the semiconductor chip 10. In the semiconductor chip 60 relating to the present second exemplary embodiment, in addition to the above-described opening portions 38, opening portions 40 at which the power source line 32 is exposed are provided due to the surface protecting film 28 being removed at, within the contact region 52, plural portions (corresponding to second portions relating to the present invention) corresponding to directly above the power source line 32 which is railed over the entire surface of the uppermost metal wiring layer 24 so as to go round the uppermost metal wiring layer 24, as shown in FIG. 4B and FIG. 5 as well.

As shown in FIG. 5, an n-type well 62 which is formed from an n-type semiconductor is formed at the semiconductor substrate 14 of the semiconductor chip 60. The power source line 32 is electrically connected, through several lower metal wiring layers 24 and vias 25, to a high-concentration n-type impurity diffusion region 64 which is formed within the n-type well 62 of the semiconductor substrate 14, such that the power source line 32 has ohmic connection to the n-type well 62. The power source line 32 corresponds to the second specific metal wire relating to the present invention. Note that, in FIG. 5, a p-type MOS transistor 70 which is formed from a pair of p-type impurity diffusion regions 66, which are formed within the n-type well 62 and which each function as a source or a drain, and a gate electrode 68 which is formed between the pair of p-type impurity diffusion regions 66, is illustrated as a portion of the integrated circuit 16 which is formed at the semiconductor substrate 14, and an unillustrated gate oxide film insulates between the gate electrode 68 and the n-type well 62.

Operation of the present second exemplary embodiment will be described next. As explained previously, in the semiconductor chip 10 described in the first exemplary embodiment, when the collet 54 approaches the top surface of the semiconductor chip 10 in the pick-up process, electrostatic discharge occurs between the ground line 30 and the collet 54 via the opening portions 38, and neutralizing charges flow into the ground line 30. Then, after the neutralizing charges, which have flowed into the ground line 30, reach the semiconductor substrate 14 through several lower metal wiring layers 24 and vias 25, the semiconductor chip 10 enters a state of electrostatic equilibrium with the electrified mounting film 50. However, an extremely short period, is required from the occurrence of the electrostatic discharge between the ground line 30 and the collet 54 via the opening portions 38 until the semiconductor chip 10 enters a state of electrostatic equilibrium with the mounting film 50, and a potential difference occurs between the ground line 30 and the power source line 32 during this time. Therefore, there is the possibility that high voltage will be applied to the integrated circuit 16 which is provided between the power source line 32 and the ground line 30.

In contrast, in the semiconductor chip 60 relating to the present second exemplary embodiment, the opening portions 40, at which the power source line 32 is exposed, are provided by removing the surface protecting film 28 also at plural portions corresponding to directly above the power source line 32, within the contact region 52 of the collet 54 on the top surface of the semiconductor chip 10. In accordance with such a structure, substantially simultaneously with the electrostatic discharge occurring between the ground wire 30 and the collet 54 via the opening portions 38 and the neutralizing charges flowing into the ground line 30, electrostatic discharge occurs also between the power source line 32 and the collet 54 via the opening portions 40 and neutralizing charges flow into the power source line 32 as well. In this way, because the potential difference between ground line 30 and power source line 32 dose not occur, high voltage is not supplied the integrated circuit 16 which is established between them. Failures such as electrostatic damage or the like can be even more reliably prevented from occurring at the integrated circuit 16 formed at the semiconductor substrate 14 due to electrostatic discharge between the semiconductor chip 10 and the collet 54 in the pick-up process.

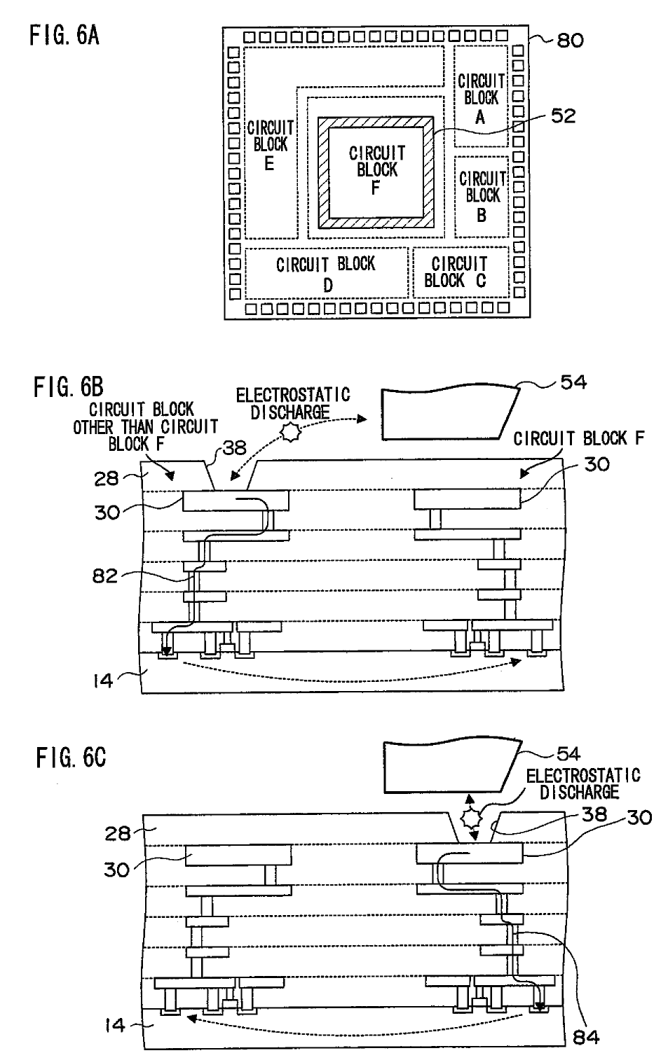

Note that the first exemplary embodiment and the second exemplary embodiment were described supposing a case in which the integrated circuit 16, which is formed on the semiconductor chip, is structured as a single circuit block having the ground line 30 and the power source line 32 in common. However, the present invention is not limited to the same. As shown as an example in FIG. 6A, the integrated circuit 16 formed at the semiconductor chip may be a set of plural circuit blocks at which the ground lines and the power source lines are provided independently of each other and which are disposed at respectively different positions on the semiconductor substrate 14. Note that FIG. 6A shows an example in which the integrated circuit formed at the single semiconductor chip is structured by six circuit blocks which are circuit blocks A through F. In a case in which plural circuit blocks are provided at a single semiconductor chip in this way, the ground lines and power source lines of any of the circuit blocks may be exposed by providing the openings 38, 40, provided that they are circuit blocks in which portions of the regions, where the corresponding ground lines and power source lines are disposed, overlap the collet contact region 52 on the top surface of the semiconductor chip.

However, in the example shown in FIG. 6A, among the circuit blocks A through F, the circuit block F is provided at a position corresponding to the collet contact region 52 on the top surface of a semiconductor chip 80. If the opening portions 38, 40 are provided and expose the ground lines and power source lines at circuit blocks other than this circuit block F, as shown in FIG. 6B, electrostatic discharge occurs between the collet 54 and the ground lines 30 (or power source lines 32) of the other circuit blocks, and the neutralizing charges, which have flowed into the ground lines 30 (or the power source lines 32) of the other circuit blocks, reach the semiconductor substrate 14 along a path 82. As in this example, some problems may occur when neutralizing charges flow into the ground lines and/or power source lines of the other circuit blocks (A through E) which are disposed away from the circuit block F. The neutralizing charges which flow into the blocks A through E reach the semiconductor substrate 14 via the path 82, and further, reach the circuit block F via the semiconductor substrate 14. The further the circuit block F is away from the circuit blocks A through E which receive neutralizing charges from the collet 54, the more time required until the neutralizing charges reach the circuit block F. In this short period, electrostatic discharge occurs between the collet and the uppermost metal wiring layer 24 belonging to the circuit block F, and there is the danger that the integrated circuit 16 of the circuit block F will be damaged.

In consideration of the above, in a case in which plural circuit blocks, at which the ground lines and the power source lines are provided independently of each other, are disposed at respectively different positions on the semiconductor substrate, it is desirable that the opening portions be provided at and expose the ground line and the power source line of at least the circuit block which is provided at the position corresponding to the collet contact region on the top surface of the semiconductor chip (circuit block F in the example of FIG. 6A). As shown in FIG. 6C, when the ground line 30 (or the power source line 32) of circuit block F is exposed by providing the opening portions 38 (or the opening portions 40), electrostatic discharge occurs between the collet 54 and the ground line 30 (or the power source line 32) of circuit block F, and the neutralizing charges which have flowed into the ground line 30 (or the power source line 32) of circuit block F reach the semiconductor substrate 14 along a path 84. Therefore, the integrated circuit of circuit block F which is most dangerous of failure such as electrostatic damage or the like will occur at the integrated circuit, can be reliably protected.

Note that, in the above-described aspect, circuit block F corresponds to the specific circuit block of the third aspect of the present invention. Providing the opening portions 38, 40 and exposing the ground line 30 and the power source line 32 of, among the plural circuit blocks, the circuit block F which is provided at the position corresponding to the collet contact region on the top surface of the semiconductor chip, corresponds to the third aspect of the present invention.

Further, the present invention is not limited to providing the opening portions and exposing the ground line and the power source line only at the circuit block which is provided at the position corresponding to the collet contact region on the top surface of the semiconductor chip, among the plural circuit blocks. If, among the plural circuit blocks, there are other circuit blocks at which portions of the regions where the corresponding ground lines and/or power source lines are disposed overlap the collet contact region 52 on the top surface of the semiconductor chip, the opening portions may be provided at the ground lines and/or power source lines of these circuit blocks as well so as to expose the ground lines and/or power source lines.

### Third Exemplary Embodiment

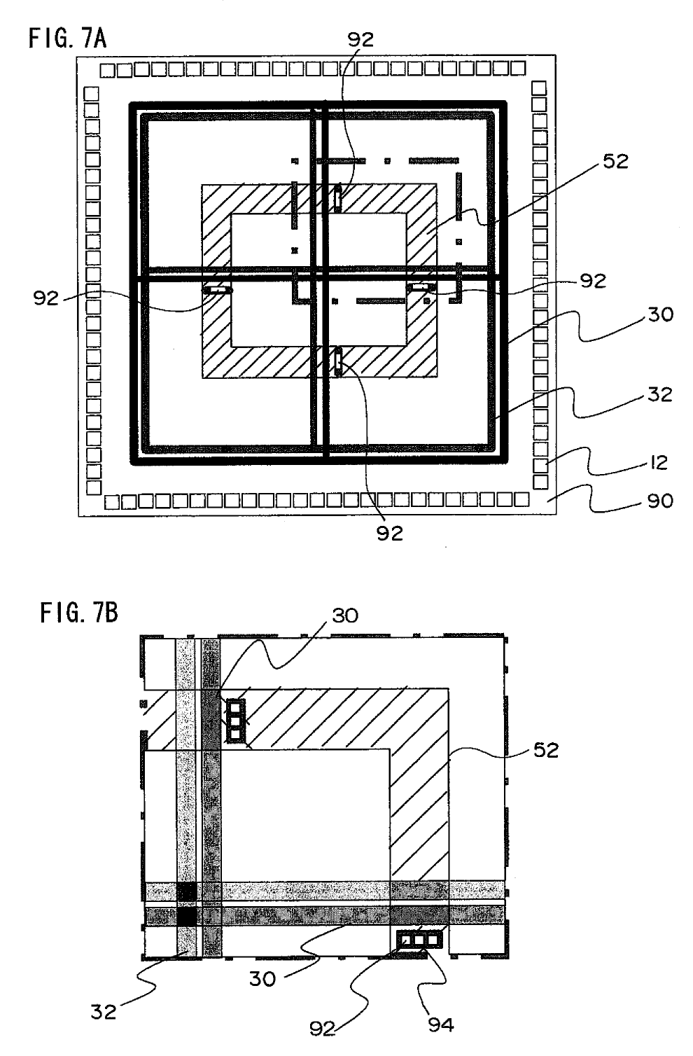

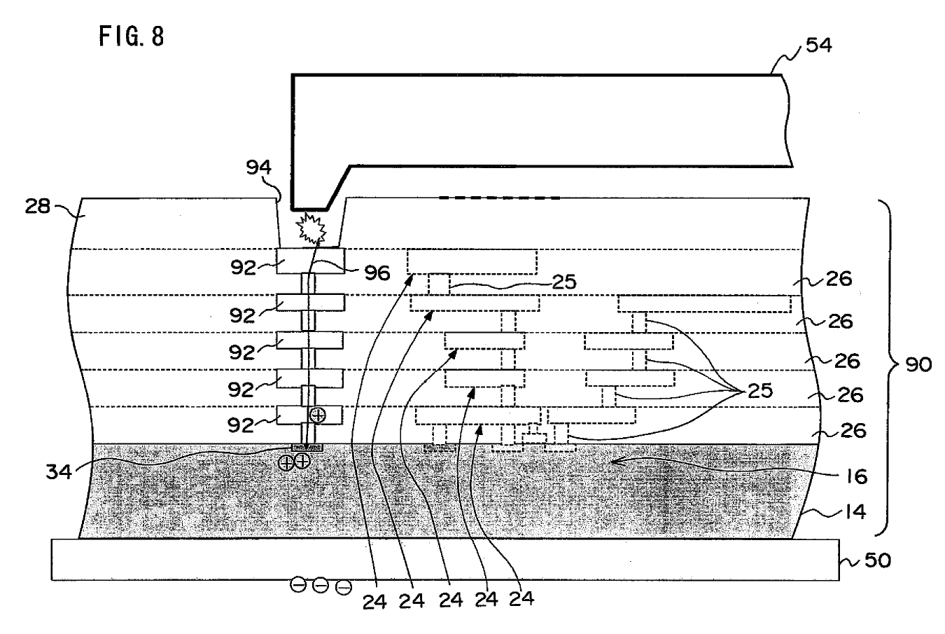

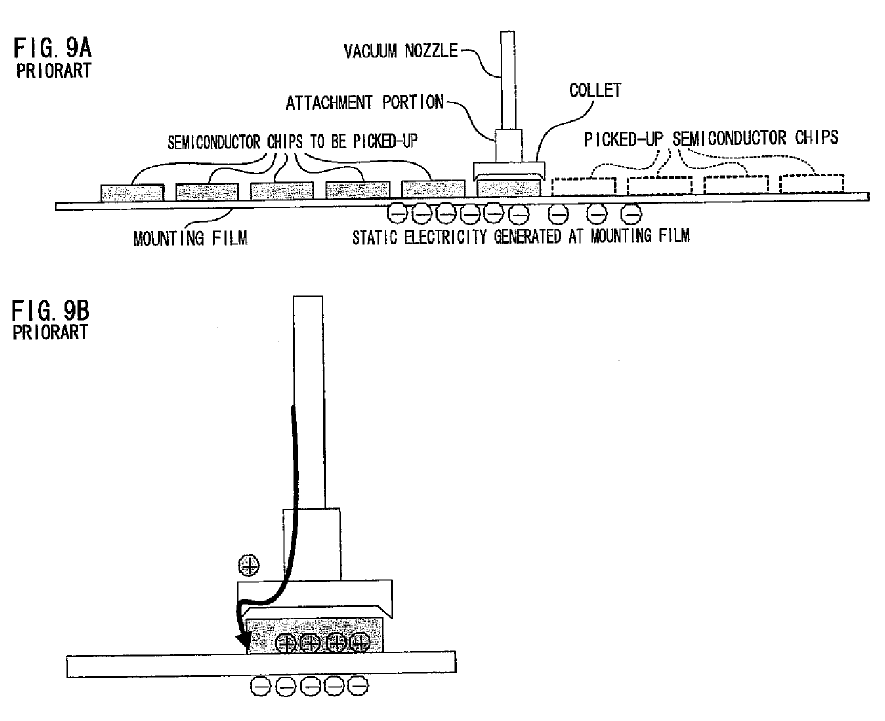

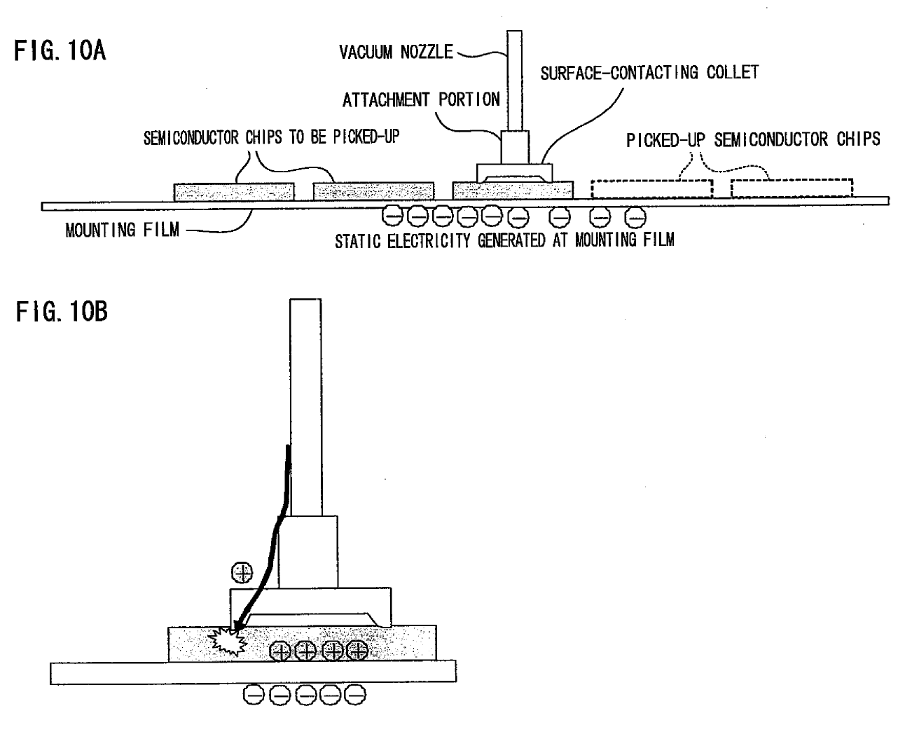

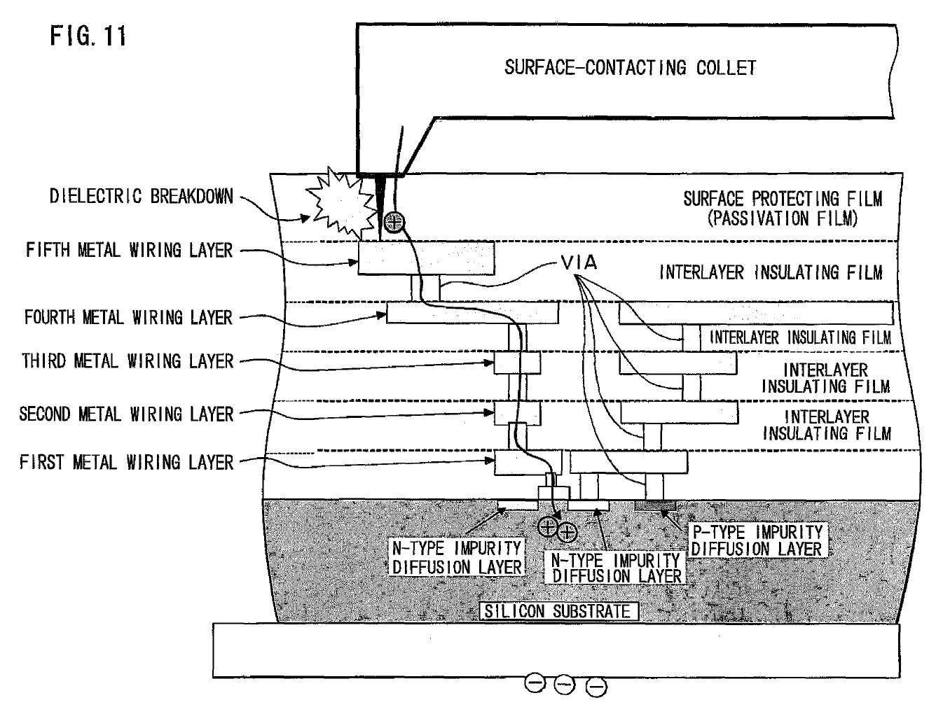

A third exemplary embodiment of the present invention will be described next. Note that portions which are the same as those of the first exemplary embodiment and the second exemplary embodiment are denoted by the same reference numerals, and description thereof is omitted. A semiconductor chip 90 relating to the present third exemplary embodiment is shown in FIGS. 7A and 7B and in FIG. 8. The opening portions 38 which were described in the first exemplary embodiment and the opening portions 40 which were described in the second exemplary embodiment are omitted from the semiconductor chip 90 relating to the present third exemplary embodiment. As shown in FIG. 8, at the semiconductor chip 90 relating to the present third exemplary embodiment, metal terminals 92 (hereinafter simply called “grounding terminals 92”), which are independent from the other metal wires which are provided in the same metal wiring layer 24 (i.e., which are not connected to the other metal wires), are provided at the respective metal wiring layers 24.

As shown in FIG. 7A, the grounding terminals 92 which are provided at the uppermost metal wiring layer 24 are respectively disposed at plural places within the collet contact region 52 on the top surface of the semiconductor chip 90. As shown in FIG. 8, the grounding terminals 92, which are provided at the metal wiring layers 24 therebeneath, are respectively disposed directly beneath the grounding terminals 92 which are provided at the uppermost metal wiring layer 24. Further, the grounding terminals 92 provided at the respective metal wiring layers 24 are connected together by vias 25, and the grounding terminals 92 which are provided at the lowermost metal wiring layer 24 are electrically connected to the high-concentration p-type impurity diffusion regions 34 which are formed on the semiconductor substrate 14. Accordingly, the grounding terminals 92 provided at the uppermost metal wiring layer 24 have ohmic connection to the semiconductor substrate 14. Moreover, as also shown in FIG. 7B and FIG. 8, opening portions 94 which expose the grounding terminals 92 are respectively provided due to the surface protecting film 28 being removed, directly above the individual grounding terminals 92 which are provided at the uppermost metal wiring layer 24. Note that the grounding terminal 92 corresponds to the first specific metal wire relating to the present invention (more specifically, the first specific metal wire of the fourth aspect of the present invention).

Operation of the present third exemplary embodiment will be described next. In the semiconductor chip 90 relating to the present third exemplary embodiment, the surface protecting film 28 of portions of the top surface of the semiconductor chip 90, which portions are within the contact region 52 of the collet 54 and correspond to directly above the grounding terminals 92, is removed such that the opening portions 94 are provided. Therefore, when the collet 54 approaches the top surface of the semiconductor chip 90 in the pick-up process, electrostatic discharge occurs, via the opening portions 94, between the collet 54 and the grounding terminals 92 which are exposed at the opening portions 94, and neutralizing charges flow into the grounding terminals 92. Then, the neutralizing charges which have flowed into the grounding terminals 92 reach the semiconductor substrate 14 along paths 96 shown in FIG. 8, and the semiconductor chip 10 enters a state of electrostatic equilibrium with the electrified mounting film 50.

Because the grounding terminals 92 relating to the present third exemplary embodiment are not provided at a conventional semiconductor chip, in order to structure a conventional semiconductor chip as the semiconductor chip 90, the grounding terminals 92 must be provided at the respective metal wiring layers 24. In addition to changing the mask pattern for providing the opening portions at the surface protecting film 28, the mask pattern for providing the respective contact terminals 92 at the respective metal wiring layers 24 and vias 25 also must be changed. However, in the present third exemplary embodiment, the grounding terminals 92 provided at each of the metal wiring layers 24 are independent from the other metal wires provided at the same metal wiring layer 24. Therefore, the paths over which the neutralizing charges, which have flowed into the grounding terminals 92, flow are electrically isolated from the integrated circuit 16 which is formed at the semiconductor chip 90. The failures such as electrostatic damage and the like, can be reliably prevented from occurring at the integrated circuit 16 formed at the semiconductor substrate 14.

Note that FIGS. 1A and 1B, FIGS. 4A and 4B, FIGS. 6A through 6C, and FIGS. 7A and 7B illustrate a rectangular frame-shaped region as an example of the shape of the collet contact region 52. However, the present invention is not limited to the same, and the shape of the collet contact region 52 depends on the shape of the bottom surface of the collet 54. Therefore, if, for example, the bottom surface of the collet 54 is oval, it goes without saying that the shape of the collet contact region 52 as well is an oval frame shape.

The number of and the arrangement of the opening portions provided at the surface protecting film 28 also are not limited to the examples shown in FIGS. 1A and 1B, FIGS. 4A and 4B, FIGS. 6A through 6C, and FIGS. 7A and 7B. The number and the arrangement of the opening portions can be appropriately changed within a scope which does not depart from the present invention. However, for example, in a case in which plural ground lines and power source lines exist at the uppermost metal wiring layer 24 as candidates for exposure by providing the opening portions at the surface protecting film 28 but there are restraints on the number of opening portions which can be provided or the like, it is preferable to select, from among the plural ground lines and power source lines which are candidates for exposure by providing the opening portions, the ground line having the widest width on the uppermost metal wiring layer 24 and the power source line which forms a pair with that ground line, and to provide opening portions at the surface protecting film 28 so as to expose the selected ground line and power source line. Generally, the ground line having the widest width on the uppermost metal wiring layer 24 is designed such that the electrical resistance of the path from that ground line to the semiconductor substrate 14 is the lowest. By providing the opening portions at the surface protecting film 28 such that such a ground line and the power source line which forms a pair with that ground line are exposed, the integrated circuit 16 formed at the semiconductor substrate 14 can be protected even more reliably.

Moreover, the sizes and configurations of the individual opening portions are not limited to the examples shown in FIGS. 1A and 1B, FIGS. 4A and 4B, FIGS. 6A through 6C, and FIGS. 7A and 7B, and can be changed appropriately. However, the integrated circuit protecting effects are better when a small number of large opening portions are provided than when a large number of small opening portions are provided, given that the total surface area of the opening portions is the same. In consideration thereof, if the ground line and the power source line which are to be exposed by providing the opening portions are metal wires whose widths are narrow on the uppermost metal wiring layer 24, it is preferable to enlarge the widths of these metal wires at the portions which are to be exposed by providing the opening portions. In this way, the integrated circuit protecting effect can be improved even if the ground line and the power source line, which are to be exposed by providing the opening portions, are metal wires whose widths are narrow on the uppermost metal wiring layer 24.

What is claimed is:

1. A semiconductor device at which an integrated circuit is formed, and at which a metal wiring layer, whose surface is covered by a protective film, is formed at an upper side of a semiconductor substrate,
wherein a first specific metal wire, which has ohmic connection to a region of a first conductive type of the semiconductor substrate, is exposed due to the protective film being removed at a first portion which is within a specific region on a surface of the protective film and which corresponds to an upper portion of, among a plurality of metal wires which are provided at the metal wiring layer, the first specific metal wire.

2. The semiconductor device of claim 1, wherein a second specific metal wire, which has ohmic connection to a region of a second conductive type of the semiconductor substrate, is exposed due to the protective film being removed at a second portion which is within the specific region and which corresponds to an upper portion of, among the plurality of metal wires which are provided at the metal wiring layer, the second specific metal wire.

3. The semiconductor device of claim 2, wherein
a plurality of circuit blocks, at which a metal wire which functions as a ground line and a metal wire which functions as a power source line are provided independently of each other at the metal wiring layer, are provided at the semiconductor device at respectively different positions on a substrate surface of the semiconductor substrate, and
the first specific metal wire is a metal wire which functions as a ground line of, among the plurality of circuit blocks, a specific circuit block which is disposed at a position corresponding to the specific region on the substrate surface of the semiconductor substrate, and the second specific metal wire is a metal wire which functions as a power source line of the specific circuit block.

4. The semiconductor device of claim 1, wherein the first specific metal wire is a metal wire which is not electrically connected to an integrated circuit formed at the semiconductor device.

5. The semiconductor device of claim 1, wherein the specific region is a region of the surface of the protective film which region is contacted by a collet in a pick-up process in which the semiconductor device is picked-up.

6. The semiconductor device of claim 2, wherein the specific region is a region of the surface of the protective film which region is contacted by a collet in a pick-up process in which the semiconductor device is picked-up.

7. The semiconductor device of claim 1, wherein the first specific metal wire includes a portion formed on a high-concentration semiconductor region of the first conductive type which is formed within the region of the first conductive type of the semiconductor substrate.

8. The semiconductor device of claim 2, wherein the second specific metal wire includes a portion formed on a high-concentration semiconductor region of the second conductive type which is formed within the region of the second conductive type of well formed on the semiconductor substrate.

9. A method of fabricating a semiconductor device comprising:
producing a semiconductor device at which an integrated circuit is formed, and at which a surface of a metal wiring layer, which is formed at an upper side of a semiconductor substrate, is covered by a protective film; and
before carrying out a pick-up process of picking-up the semiconductor device, exposing a first specific metal wire, which is electrically connected to a region of a first conductive type of the semiconductor substrate, at a first portion by removing the protective film at the first portion which is within a specific region on a surface of the protective film and which corresponds to an upper portion of, among a plurality of metal wires which are provided at the metal wiring layer, the first specific metal wire.

10. The method of manufacturing a semiconductor device of claim 9, wherein, before the pick-up process is carried out, a second specific metal wire, which is electrically connected to a region of a second conductive type of well formed on the semiconductor substrate, is exposed at a second portion due to the protective film being removed at the second portion which is within the specific region and which corresponds to an upper portion of among the plurality of metal wires which are provided at the metal wiring layer, the second specific metal wire.

11. The method of manufacturing a semiconductor device of claim 9, wherein the specific region is a region of the surface of the protective film which region is contacted by a collet in the pick-up process in which the semiconductor device is picked-up.

12. The method of manufacturing a semiconductor device of claim 10, wherein the specific region is a region of the surface of the protective film which region is contacted by a collet in the pick-up process in which the semiconductor device is picked-up.

13. The method of manufacturing a semiconductor device of claim 11, wherein a bottom surface area of the collet is smaller than a surface area of a surface of the semiconductor device, which surface has a region that the collet contacts.

14. The method of manufacturing a semiconductor device of claim 12, wherein a bottom surface area of the collet is smaller than a surface area of a surface of the semiconductor device, which surface has a region that the collet contacts.
